(19) United States
(12) Patent Application Publication
(10) Pub. No.: US 2009/0127690 A1
(43) Pub. Date: May 21, 2009

(54) Package and Manufacturing Method for a Microelectronic Component

(75) Inventors: Dandy N. Jaducana, Laguna (PH); Johnathan S. Catalla, Laguna (PH); Nhoy Lacson, Sta. Rosa City (PH); Jose O. Amistoso, Laguna (PH)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/996,331

(22) PCT Filed: Jul. 13, 2006
(86) PCT No.: PCT/IB2006/052385

§ 371 Date: Nov. 21, 2008

(30) Foreign Application Priority Data
Jul. 28, 2005 (EP) 05106971.4
Jul. 13, 2006 (IB) PCT/IB2006/052385

(51) Int. Cl. H01L 23/31; H01L 21/56

(52) U.S. Cl. 257/690; 438/127; 257/E23.123; 257/E21.502

(57) ABSTRACT

The present invention relates to A package (50,70) for a microelectronic component, comprising: a carrier element (12) having a first side (16) that comprises conductor lines (14); —a microelectronic component (20) having a first surface (24) and a second surface (23) facing away from the first surface; the microelectronic component with said second surface mounted on said first side and connected to the conductor lines via bonding wires (28); a polymeric encapsulation material (30) encapsulating the bonding wires and exposing a central zone (40) of said first surface (24), the encapsulation material comprising an outer edge (36) at said first side and an inner edge (38) at said first surface; a dam (42,44) abutting to the encapsulation material; wherein the dam (44) comprises a step-shaped surface transition (46) at said first side (16), the surface transition abutting on said outer edge (36). The dam (44) influences the forming of the outer (36) and the inner edge (38) during manufacturing the encapsulation material (30) and enlarges the area of the central zone (40). The present invention also relates to a method of manufacturing such a package for a microelectronic component.

The present invention relates to a package for an microelectronic component, comprising a carrier element having conductor lines, a microelectronic component mounted on the carrier element and connected to the conductor lines via bonding wires, and an encapsulation material encapsulating the wire bonds and exposing a central zone of a top surface of the microelectronic component.

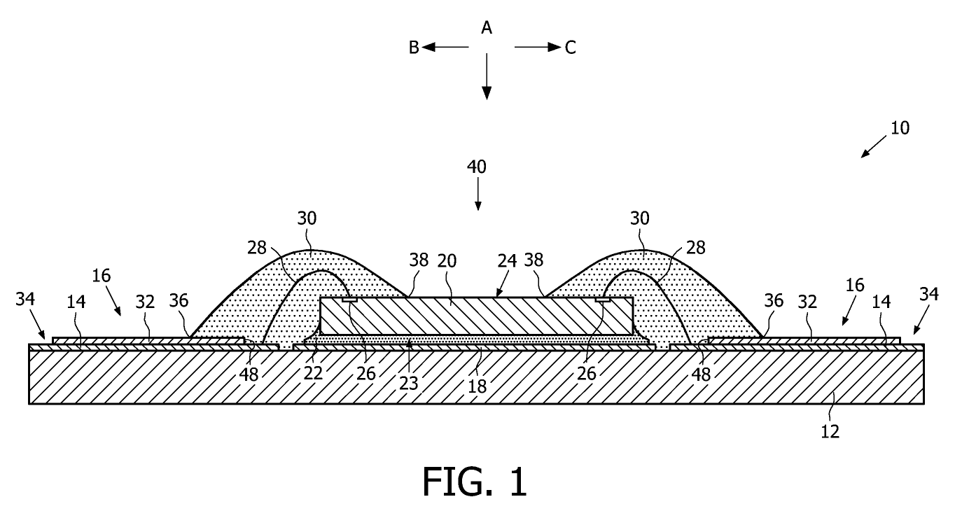

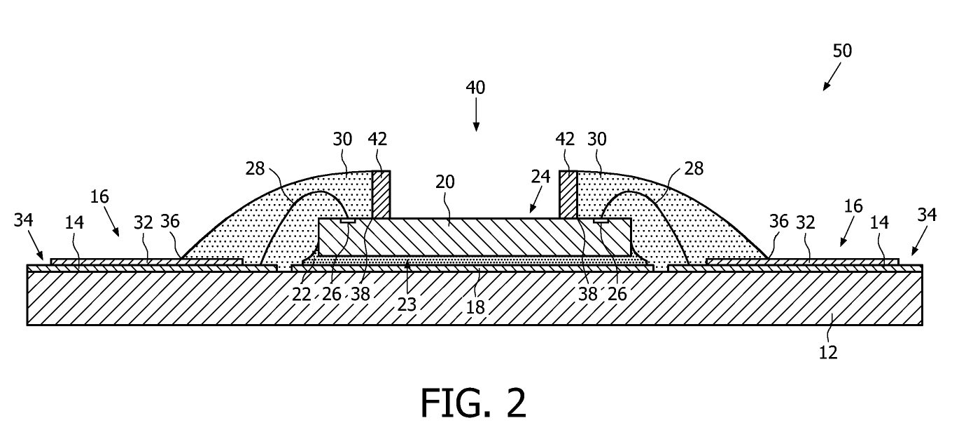

Such packages for microelectronic components are commonly known. The following is a description of two general designs of such packages known in the prior art giving an introduction to the present invention. These designs are shown in FIGS. 1 and 2, in which same reference numerals indicate same or similar parts. FIG. 1 shows a schematic cross-section of a package for a microelectronic component. The package 10 comprises a carrier element 12 having a first side 16 that comprises conductor lines 14. A microelectronic component 20 is mounted on a diepad 18 of the substrate through an adhesive 22, which usually is an electrically and/or thermally conductive adhesive. In this way the diepad, which preferably comprises a gold top layer, can act as heat sink and grounding area. Typically the microelectronic component and diepad have a quadrangular or even a square shape. The microelectronic component 20 has a first surface 24 and a second surface 23 facing away from the first surface. It is connected to the first side 16 of the carrier element 12 with its second surface 23. The microelectronic component 20 comprises contact terminals 26 or bond pads that are schematically indicated in the drawings. The contact terminals 26 are connected to respective conductor lines 14 via respective wire bonds 28, for instance thin gold wires, having one end attached to a conductor line 14 and having the other end attached to the microelectronic component 20. The conductor lines provide input and/or output terminals for the complete package that functions as a microelectronic device, to receive or provide input signals or output signals. Since the methods for attaching such bonds are known per se, it is not necessary here to explain such methods in greater detail.

An outside layer 32, such as a solder resist layer, covers parts of the conductor lines 14 of the carrier element 12, the layer 32 determining connection areas 34 at the first side 16. The connection areas 34 are used to connect the microelectronic device to the outside world. For instance the areas 34 can be soldered or connected otherwise with connectors or terminals of other electronic devices or components. Such connections are also commonly known and do not need further explanation here.

The assembly of carrier element 12, microelectronic component 20 and bonding wires 28 is partially encapsulated by an encapsulation material 30. This encapsulation material typically comprises a polymeric material that is injected on the respective area by some sort of injection device. Usually an epoxy-based material is used that cures after injecting it and forms a closed loop of epoxy material around the microelectronic component. The injection device is positioned just above the first side and first surface respectively and moves in the desired pattern while dispensing the epoxy material, the epoxy material after hardening resulting in the loop mentioned. In the prior art the encapsulation material 30 is sometimes referred to as top glob material or glob top ring. After curing the encapsulation material 30 determines an outer edge 36 at the first side 16 and an inner edge 38 at the first surface 24 respectively.

The inner edge 38 determines a central zone 40 of the microelectronic component that is exposed. Many different types of microelectronic devices require an opening in the encapsulating plastic package that exposes a sensitive or active area to the surrounding environment. A first example is micro-electromechanical systems (MEMS), such as airbag accelerometers and gyroscopic devices, which comprise freestanding structures that must be able to move, rotate, etc. Likewise, micro-sensors that have chemically sensitive, pressure-sensitive, or temperature sensitive areas must be exposed to the environment through an area on the surface of the sensor that is freely exposed. Finally, optically active microelectronic devices require optical access through an opening or an exposed zone in the plastic package. Examples of optically active devices are charged coupled devices (CCD), photocells, photodiodes, and vertical cavity surface emitting lasers (VCSEL's). While some of these devices emit light while others receive light; both are considered to be ‘optically active’. All devices have in common that they comprise sensor elements on a surface that must be freely exposed to the environment to provide or receive their respective input or output signals from the outside world. The functioning of these types of microelectronic devices is known per se and therefore not discussed here in greater detail.

A problem of this microelectronic device as shown in FIG. 1 is that the total surface area of the central zone 40 is difficult to control. When the encapsulation material is injected it will flow in the direction indicated by arrows A, B and C in FIG. 1. The final shape of the encapsulation material is at least dependent on the parameters of the injection process, the material properties of the injected material, especially its rheology properties, the exact geometry of the package prior to injection, and the curing parameters. Regarding the many influencing factors it is very difficult to obtain high process reliability with respect to the total surface area of the central zone when injecting the encapsulation material. This can result in a reduced operating window for the sensor elements on the microelectronic component that must be freely exposed and thus correspondingly in high yield losses. When the central zone is restricted too much, the microelectronic component cannot function properly. Thus there is a need to influence or control the final shape of the encapsulation material, in particular with respect to the forming of the inner edge thereof.

U.S. Pat. No. 6,674,159 offers a solution for the problem mentioned in the previous paragraph by disclosing a package similar to the package from FIG. 1. This package is shown in FIG. 2; a package 50 comprises a dam 42 that is placed or otherwise fabricated on top of the first surface 24 of the microelectronic component 20. It should be noted that the actual microelectronic device disclosed in U.S. Pat. No. 6,674,159 has a somewhat different design with respect to the construction of the connection of the microelectronic component on the carrier element and for example has no diepad but a window of optical transparent material instead. However this difference is not relevant with respect to the present invention. Relevant is that the package U.S. Pat. No. 6,674,159 also has a microelectronic component with a central zone on a top surface that should be exposed with respect to incoming and outgoing signals from the outside world and that the component is mounted on a substrate or carrier element, both components being connected by bonding wires. A polymeric encapsulation material 30 is poured or otherwise dispensed into the region outside of dam 42 around the bonding wires 28 to encapsulate and protect them. The dam 42 encircles the central zone 40 and prevents encapsulation material 30 from flowing into the central zone 40.

A clear disadvantage of the solution as proposed in U.S. Pat. No. 6,674,159 is that the dam occupies quite some valuable space of the top surface of the microelectronic device. This will reduce the area that is available for the contact terminals and/or the sensor elements. Moreover this surface comprises sensitive microelectronics that can be easily damaged when mounting the dam on the microelectronic component. Another disadvantage is that mounting the dam to the surface of the microelectronic component for example by an adhesive layer might results in contamination of the bondpads that are located nearby. Finally the forming and mounting of the dam gives an additional process step during manufacturing of the package.

It is an object of the present invention to provide a package for a microelectronic component that can be manufactured so as to obtain an exposed zone having sufficient surface area while the corresponding top surface is kept undisturbed. Therefore the present invention provides a package for a microelectronic component, comprising;

a carrier element having a first side that comprises conductor lines;

a microelectronic component having a first surface and a second surface facing away from the first surface; the microelectronic component with said second surface mounted on said first side and connected to the conductor lines via bonding wires;

a polymeric encapsulation material encapsulating the bonding wires and exposing a central zone of said first surface, the encapsulation material comprising an outer edge at said first side and an inner edge at said first surface;

a dam abutting to the encapsulation material;

wherein the dam comprises a step-shaped surface transition at said first side, the surface transition abutting on said outer edge. The present invention is based on the insight that having such a surface transition at the first side not only influences the creation of the outer edge of the encapsulation material but also its inner edge. Experiments have shown that such a dam not only restricts the outward flow of the encapsulation material as indicated with direction B in FIG. 1 but surprisingly also restricts the inward flow indicated by direction C and with that enlarges the central zone. Thus the dam influences the forming of the outer and the inner edge during manufacturing the encapsulation material. This allows an improved control of the total area of the central zone and ensures that this surface area is kept above a critical level. Therefore an improved process capability during injecting the encapsulation material is obtained. A complete theoretical explanation for this phenomenon has not yet been found, but would go beyond the scope of the present disclosure anyway. It is assumed that since the outer edge abuts on the surface transition the contact angle at the first side considerably increases, which via a changed surface tension working on the encapsulation material during curing also influences the contact angle at the first surface or at the inner edge.

In a preferred embodiment an outside layer is provided at the first side, said layer protecting parts of the conductor lines, wherein said surface transition is arranged between said outside layer on the one hand and said conductor lines and a lower layer at said first side on the other. Preferably the outside layer is a solder resist layer. The solder resist layer is specifically designed to both protect the conductive surface tracks and prevent solder bridges during soldering. Such layers are frequently applied on a carrier element before mounting the microelectronic component. Since normally some kind of surface transition between this outside layer and a first layer under it or the conductor lines already exists, the outside layer can advantageously be used to create the dam. In this case one should make sure that an edge of the outside layer creating the surface transition is placed correctly and it has sufficient thickness.

According to another preferred embodiment the dam comprises a top layer disposed at said first side adjacent to said outer edge. It is preferred in particular that this top layer forms a strip with a rectangular shape. This allows applying existing carrier elements, which only need an additional top layer to make them suited for a package according to the invention. By applying the layer in the form of a rectangular strip it is ensured that a minimum amount of additional material is needed and that the encapsulation material adopts a preferred shape.

According to another preferred embodiment the height of the dam is less than a tenth of the height of the encapsulation material. It has been found that only a little material creating a step-shaped surface transition at the first side satisfies to obtain the object of the present invention.

The present invention also relates to a carrier element to be used in a package for a microelectronic component according to any of the inventive embodiments mentioned before.

The present invention also relates to a microelectronic device comprising a package for a microelectronic component according to any of the inventive embodiments mentioned before.

The present invention furthermore also relates to method of manufacturing a package for a microelectronic component, the method comprising;

providing a carrier element having conductor lines at a first side;

providing a dam comprising a step-shaped surface transition at the first side; mounting a microelectronic component having a first surface and a second surface facing away from the first surface, the second surface of the microelectronic component connecting to the first side of the carrier element;

wirebonding the microelectronic component to the conductor lines;

dispensing a fluid polymeric encapsulation material to the assembly of the carrier element and the microelectronic component to encapsulate the wire bonds while exposing a central zone of the first surface, the encapsulation material with an outer edge abutting on the surface transition;

curing the encapsulation material in a furnace.

It is preferred that the step of providing a dam at the first side comprises applying a top layer on the first side in the shape of a rectangular strip. Such methods allow the manufacturing of packages with a central zone having sufficient surface area while leaving the first surface undisturbed and which require only small modifications to the existing components.

It should be noted that U.S. Pat. Nos. 6,861,683 and 6,303,978 show a package for a microelectronic component with a dam provided at the first side of the carrier element, which dam abuts on the outer edge of the encapsulation material. However an important difference with these packages is that the encapsulation material fills the space between the dam and the carrier element completely and does not leave a central zone that is exposed to the environment. By applying a transparent encapsulation material the package indeed can be used for microelectronic devices requiring an ‘optically active area’ for providing and receiving optical signals, but such a package clearly can not be used for microelectronic components such as for example MEMS systems or devices comprising sensor elements on a top surface that are sensitive to heat, pressure or chemical substances.

Aspects as mentioned above as well as other aspects, features and advantages of the present invention will be further explained by the following description with reference to the drawings, in which same reference numerals indicate same or similar parts, and in which:

FIG. 1 is a cross-sectional view showing a package for a microelectronic component according to the prior art;

FIG. 2 is a is a cross-sectional view showing another package for a microelectronic component according to the prior art;

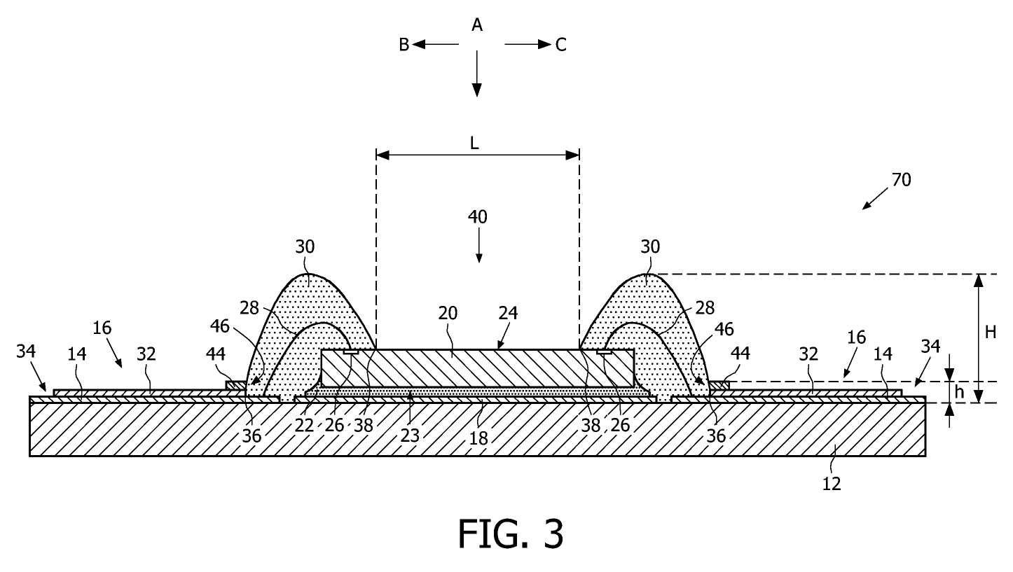

FIG. 3 is a cross-sectional view showing a preferred embodiment of a package for a microelectronic component according to the invention;

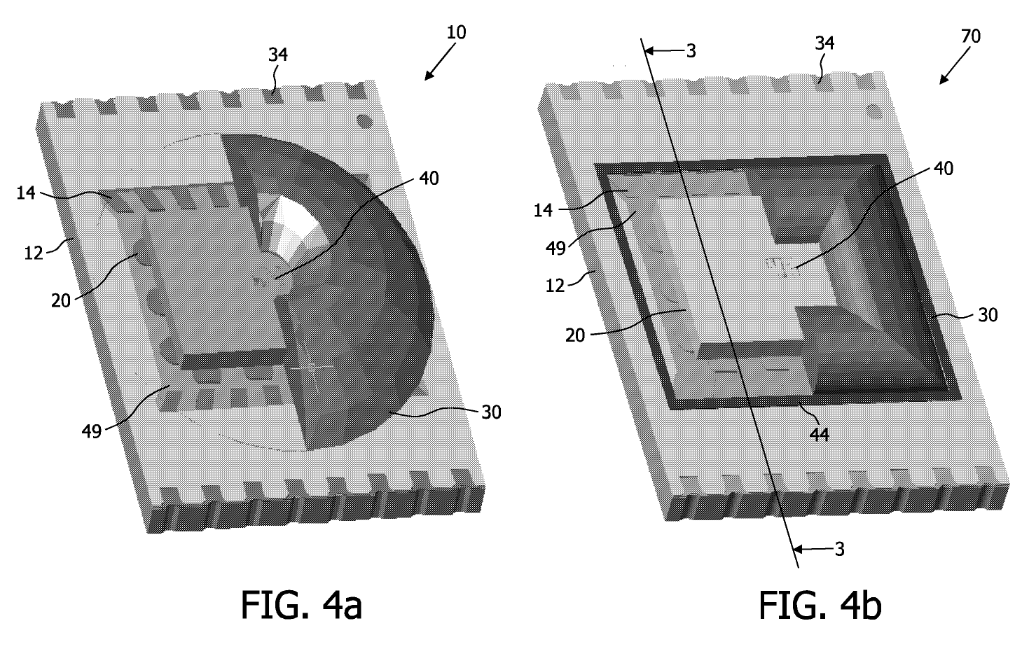

FIGS. 4a and b are perspective top views showing packages for a microelectronic component according to the prior art (FIG. 4a) and according to the invention (FIG. 4b) respectively.

In FIG. 3 a cross-sectional view of a package 70 is shown, which is taken along line 3-3 in FIG. 4b. The package 70 comprises a dam 44 provided on the outside layer 32 of the first side 16. The dam comprises a step-shaped surface transition 46 that is arranged between the outside layer 32 and the conductor lines 14 or a layer 49 under the outside layer (see FIGS. 4a and b). It influences the shape of the glob top material 30 during its curing so as to enlarge the width L of the central zone 40 and thus enlarge the surface area thereof. Disposing a respective inner edge 48 (see FIG. 1) of the outside layer 32 facing the encapsulation material at a proper location and applying an additional layer on top of layer 32 with an edge parallel to said edge of layer 32 forms the dam 44, as it is shown in FIG. 3. Alternatively edge 48 of the outside layer is disposed more to the outside of the carrier element 12 while the additional layer is applied on top of the conductive tracks and a first lower layer, the strip shaped additional layer abutting on the outside layer 32 and the outer edge 36 respectively. Preferably the top layer is made somewhat thicker in this case, or at least thicker than outside layer 32.

Preferably the outside layer 32 is a solder resist layer, which is usually applied for these types of packages to cover and protect the conductive surface tracks.

An alternative to create a surface transition at the first side is to arrange a groove in the outside layer 32, a substantially vertical outer wall thereof acting as the required surface transition. For this embodiment the outside layer 32 should have sufficient thickness. Another possibility is starting from the embodiment in FIG. 1 and without applying any additional layers disposing the outside layer 32 such that the inner edge 48 (see FIG. 1) thereof is shifted to the outside of the carrier element 12 (direction B and C). In this way the inner edge 48 can form the surface transition, the encapsulation material 30 abutting on this edge. With this embodiment also the outside layer 32 should have sufficient thickness. The layer thickness of the protective outside layer as it is used at present generally will not be sufficient.

The step-shaped surface transition according to the invention should be such that it influences or rather increases the contact angle of the encapsulation material abutting on such a transition at the first side as compared to the situation wherein the first side in the area around the outer edge of the encapsulation material is flat. It does not necessarily require a straight vertical wall between the two surfaces adjacent to the transition.

The height h of the dam preferably is much lower compared to the height H of the glob top ring 30, which is at least ten times as large. Typical dimensions are 400 μm height for the glob top and 20-30 μm height for the dam. Experiments have indicated that for packages with an original surface area of 2.75 mm², this area increased to 5.724 mm² when a dam according to the invention was applied on the first side.

The carrier element 12 can be any element comprising a conductive or metallic structure that is embedded in a non-conductive matrix material and that is suited to accommodate a microelectronic component.

The creation of the dam 44 can be integrated with the manufacturing of the carrier element 12. Preferably one adds an additional top layer of solder resist, the top layer forming a strip with a rectangular shape. Together with the relatively small height of the dam this means that not only few additional material is needed but also that the additional processing is relatively little in order to create a working embodiment according to the present invention. The additional processing is in particular little compared to the additional manufacturing that is required to obtain the dam as disclosed in U.S. Pat. No. 6,674,159. In these cases the additional work is part of the manufacturing process of the package itself and involves processing steps with the microelectronic component, while according to the present invention it only involves a small modification of the carrier element.

The strip shaped dam can be formed on an existing carrier element or substrate in the following manner. First a layer of liquid solder resist material is screen printed on top of the outside solder resist layer at the first side. Then a mask that exposes a rectangular strip is placed over this layer, which strip is cured by means of UV light. Finally the unexposed parts are chemically stripped, leaving the required dam configuration.

FIGS. 4a and 4b show perspective top views showing a package 70 for a microelectronic component according to the invention and a package 10 according to the prior art respectively. FIG. 4b more clearly shows the dam 44 having the form of a rectangular strip, the encapsulation material 30 abutting the strip. Preferably the strip is square. The dam comprises a step-shaped surface transition between a top surface of the strip and the conductive tracks 14 or a first lower layer 49 (directly under the outside layer 32) respectively. For reasons of clarity only half of the glob top material is shown. The encapsulation material 30 exposes a central zone 40 to the environment of which the surface area is larger and better to control when curing the glob top material in case of the presence of dam 44. This is clearly illustrated by comparing the glob top material 30 from FIGS. 4a and 4b respectively.

For the encapsulation material preferably an epoxy material, such as Hysol® FP4323 is used. The encapsulation material is dispensed on the package with a CAMALOT 3700 epoxy dispenser, which has an injection needle operating with a dispensing speed of 10-20 mm/s, an air pressure of 40-60 psi and a height of 0.7-0.8 mm from the microelectronic component. After dispensing the epoxy material it is cured in an oven at about 170° C. for approximately 3 hours.

The invention can be applied for all packages requiring an exposed central area on a top surface of a microelectronic component. These packages have been discussed before when discussing the prior art as shown in FIGS. 1 and 2. A typical example is to apply the package for photodiode integrated circuits. A single optical pick-up IC for example can be used for read/write applications to make an optical processing unit that is suitable for all kinds of CD and DVD devices. The package according to the invention is furthermore applicable for ball grid array (BGA) type of packages and for bulk acoustic wave filters.

One applies a package according to the invention in particular advantageously for photodiode devices that are used in so-called blue-ray disc apparatus'. These apparatus' use ultraviolet laser beams. The polymeric or epoxy materials known at present cannot withstand this type of laser radiation. This means that making use of an optically transparent material instead of leaving an exposed central zone is not an option for these blue-ray devices. Furthermore it is important that the central zone has a sufficient area ensuring that the laser radiation does not harm the encapsulation material.

The microelectronic component can be any suitable component, such as integrated circuits, photocells or MEMS elements. Furthermore it is possible to combine several microelectronic components that are mutually connected within the package (also referred to as system in package). In case MEMS elements are present at a first surface of the microelectronic component it could be advantageous to cover the exposed area with some kind of lid (not shown in the drawings) that is connected to an outer area of the encapsulation material. Such elements in general must be able to rotate, translate, etc in a free space but for the rest are preferably protected from the surrounding environment.

It should be clear to a person skilled in the art that the present invention is not limited to the exemplary embodiments discussed above, but that several variations and modifications are possible within the protective scope of the invention as defined in the appending claims.

1. A package for a microelectronic component, comprising:
a carrier element having a first side that comprises conductor lines;
a microelectronic component having a first surface and a second surface facing away from the first surface; the microelectronic component with said second surface mounted on said first side and connected to the conductor lines via bonding wires;
a polymeric encapsulation material encapsulating the bonding wires and exposing a central zone of said first surface, the encapsulation material comprising an outer edge at said first side and an inner edge at said first surface;
a dam abutting to the encapsulation material;
characterized in that the dam comprises a step-shaped surface transition at said first side, the surface transition abutting on said outer edge.

2. A package for a microelectronic component as claimed in claim 1, characterized in that an outside layer is provided at the first side, said layer protecting parts of the conductor lines, and that said surface transition is arranged between said outside layer on the one hand and said conductor lines and a lower layer at said first side on the other.

3. A package for a microelectronic component as claimed in claim 1, characterized in that the dam comprises a top layer disposed at said first side adjacent to said outer edge.

4. A package for a microelectronic component as claimed in claim 3, characterized in that said top layer forms a strip with a rectangular shape.

5. A packager for a microelectronic component as claimed in claim 1, characterized in that the height of the dam is less than a tenth of the height of the encapsulation material.

6. A carrier element to be used in a package for a microelectronic component according to claim 1.

7. A microelectronic device comprising a package for a microelectronic component according to claim 1.

8. Method of manufacturing a package for a microelectronic component according to claim 1, the method comprising;
providing a carrier element having conductor lines at a first side;
providing a dam comprising a step-shaped surface transition at the first side;
mounting a microelectronic component having a first surface and a second surface facing away from the first surface, the second surface of the microelectronic component connecting to the first side of the carrier element;
wirebonding the microelectronic component to the conductor lines;
dispensing a fluid polymeric encapsulation material to the assembly of the carrier element and the microelectronic component to encapsulate the wire bonds while exposing a central zone of the first surface, the encapsulation material with an outer edge abutting on the surface transition;
curing the encapsulation material in a furnace.

9. Method of manufacturing a microelectronic component according to claim 7, the step of providing a dam at the first side comprises applying a top layer at the first side in the shape of a rectangular strip.
